(19) United States
(12) Patent Application Publication
(10) Pub. No.: US 2003/0030446 A1
(43) Pub. Date: Feb. 13, 2003

(54) Method for providing compensation current and test device using the same

(76) Inventors: Simon Wang, Taipei (TW); Shauk-Soe Tone, Hsin-Tien City (TW); Eddie Chang, Hsin-Tien City (TW)

Correspondence Address: BUCKNAM AND ARCHER, 1077 Northern Boulevard, Roslyn, NY, 11576, US

(21) Appl. No.: 10/267,075

(22) Filed: Oct. 8, 2002

Related U.S. Application Data
(63) Continuation-in-part of application No. 09/675,546, filed on Sep. 28, 2000.

(51) Int. Cl. G01R 31/08

(52) U.S. Cl. 324/525

(57) ABSTRACT

The present invention relates to a method for providing compensation current and test device using the same, the method comprising: using a standard test voltage value as a standard voltage value for a standard voltage value for a subsequent compensation calculation; reading a test voltage value and a leakage current after connecting an object to be tested to a connecting point; and calculating a simulated compensation value of a dynamic leakage current in accordance with an equation.

The test device using the method comprises: a system control device for providing control signals for each of devices and connecting to a displaying device, a ground impedance current generation device, a dynamic leakage current test device, AC/DC voltage test devices, each of test values is sent back to the system control device for analysis via an analog/digital converter after testing an object by using the dynamic leakage current test device.

This is a continuation-in-part application of application Ser. No. 09/675,546, filed Sep. 28, 2000.

### FIELD OF THE INVENTION

The present invention relates to a method for providing compensation current and a test device using the same, and particularly, to a five-in-one test device for automatically calculating simulated compensating value for leakage current in AC voltage test, DC voltage test, insulation impedance test, ground impedance test, and line leakage current test.

### BACKGROUND ART

Conventionally, in the safety specification testing, a leakage current test is carried out with +6% of power supply designated voltage as the standard of voltage input. Therefore, an AC power supply must be used to achieve a voltage input of +6% when performing leakage current test. However, a method using this conventional technique not only increases the cost of apparatus and energy consumption but also causes the space on test site. Moreover, a conventional safety specification test device has only testing function of AC voltage test, DC voltage test, insulation impedance test, and grounded impedance test, so that an additional apparatus must be used to perform the test of dynamic leakage current, resulting in a waste of both space and efficiency.

Therefore, there is a need to develop a safety specification test device with a real time leakage current self-simulated compensation, in other words, to develop a five-in-one safety specification test device for providing compensation current, and its test method.

### SUMMARY OF THE INVENTION

The present invention is to provide a method for providing compensation current and a test device using the same. A main object of which is to provide a circuit having function of automatically calculating simulated compensating value for a dynamic leakage current. At test, a simulated compensation value of a dynamic leakage current can be calculated by using a standard test voltage value as a standard voltage value for a standard voltage value for a subsequent compensation calculation; reading a test voltage value and a leakage current after connecting an object to be tested to a connecting point; and calculating a simulated compensation value of a dynamic leakage current in accordance with an equation and these relevant values including the standard voltage value, test voltage value and leakage current.

Another object of the present invention is to calculate automatically a simulated compensation value for a dynamic leakage current in accordance with an equation by using a theory of constant ratio in a non-ideal input condition. This solution can be broadly applicable for a design of multi-function safety specification test device or individually for a test device for a dynamic leakage current.

Still another object of the present invention is to combine various devices having various functions into a five-in-one test device which is also referred to as a multi-function test device without increasing a cost and a space.

In order to achieve above objects, in accordance with the present invention, there is provided a method for providing compensation current using a standard test voltage value as a standard voltage value for a subsequent compensation calculation; reading a test voltage value and a leakage current after connecting an object to be tested to a connecting point; and calculating a simulated compensation value of a dynamic leakage current I_{S} in accordance with a following equation: I_{S}=(V_{R}/V_{M})·I_{M}, wherein V_{R} represents the standard test voltage value, V_{M} represents the test voltage value, I_{M} represents the test current value, and I_{S} represents the simulated compensation value. The test device using the above method has functions of AC voltage test, DC voltage test, insulation impedance test, ground impedance test, and line leakage current test, and comprises: a system control device for providing control signals for each of devices and connecting to a displaying device, a ground impedance current generation device, a dynamic leakage current test device, AC/DC voltage test devices, each of test values is sent back to the system control device for analysis via an analog/digital converter after testing an object by using the dynamic leakage current test device.

### BRIEF DESCRIPTION OF DRAWINGS

The above and other objects, features, and advantages of present invention will become more apparatus from the detailed description in conjunction with the following drawings:

FIG. 1 is a flow chart showing a test method having a function of dynamic leakage current self-simulated compensation according to present invention;

FIG. 2 is a schematic block diagram showing a five-in-one test device having a function of dynamic leakage current self-simulated compensation according to present invention;

FIG. 3 is a schematic diagram showing an output sensing AC high voltage generating/reading device according to present invention; and

FIG. 4 is a conventional output sensing AC high voltage generating/reading device according to prior art.

### DETAILED DESCRIPTION OF THE INVENTION

The test device provided by the present invention is of fast speed and simplicity, and is capable of achieving five necessary tests for electronic safety specifications including leakage current test, AC voltage test, DC voltage test, insulation impedance test, ground impedance test, without any connection change. For example, for leakage current test, in short, the employed method can calculate a simulated compensation value for a dynamic leakage current by reading a test voltage value and a dynamic leakage current value and using an equation. The following are brief descriptions for these tests in order to illustrate main feature of each of these tests:

1. AC Voltage Test

It predict performs AC dielectric testing over the voltage range from 50 to 5000V AC rms. Leakage current detection is programmable from 1 μA to 40 mA. It makes testing medical products and instruments having a wide range of leakage currents.

2. DC Voltage Test

DC dielectric testing is programmable from 50 to 6000V DC with leakage current detection down to 0.1 μA. The maximum output current is up to 20 mA. This allows quick charging of capacitive devices and products.

3. Insulation Impedance Test

The insulation Impedance test calculates and displays a product's insulation resistance value in ohms. This resistance can be measured over the range from 100 kΩ to 50 kΩ with test voltages programmable from 50 to 1000V DC in a step of 1V.

4. Ground Impedance Test

The ground Impedance Test, sometimes referred to as a high current continuity test, can be programmed from 1 to 30 A in a step of 0.01 A for verifying the integrity of a product's ground system. Resistance measurements are displayed and programmed the limit between 0.1 m and 510 m.

5. Line Leakage Current

Line leakage Current tests can be performed directly on the tester in several configurations including: (1) Normal operating condition (2) Reverse line, (3) Single fault normal, (4) Single fault reverse mode, (5) Ground set on or off.

Leakage current limits are programmable from 0.1 μA to 9.999 mA. An optional isolation transformer is available for line leakage testing.

The test device of the present invention is a multi-function test device having functions of AC voltage test, DC voltage test, insulation impedance test, ground impedance test and line leakage current test, wherein the line leakage current test of the multi-function test device comprising: a fixed voltage power supply; a system control device, for providing selection of test and control signals for each of devices and connecting with a displaying device; a leakage current for a leakage current and setting a voltage value for testing the leakage current, wherein a simulated compensation value of a dynamic leakage current is calculated by: connecting an object to be tested to a connecting point for reading a test voltage value and a leakage current value, and calculating the simulated compensation value of the dynamic leakage current by using the set voltage value, the test voltage value and leakage current value.

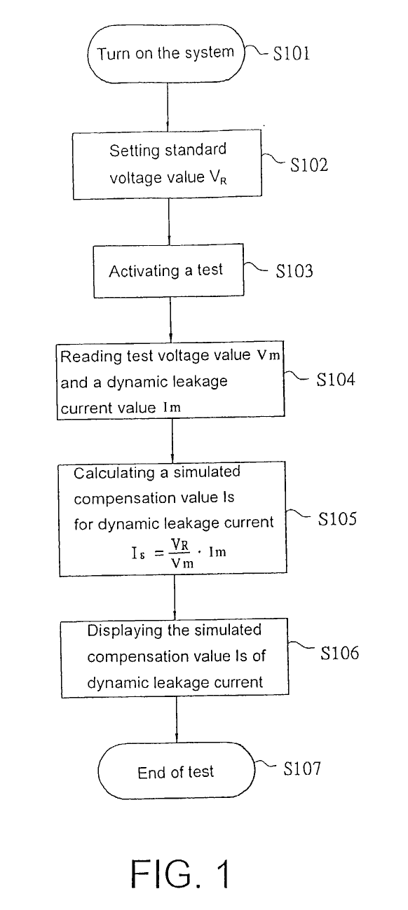

As shown in FIG. 1, a flow chart of a test method having a function of dynamic leakage current self-simulated compensation according to present invention. First turning on (Step S101) the system, setting a standard voltage value V_{R} (Step S102), activating the test device (Step S103), reading a test voltage value V_{M} and a dynamic leakage current value I_{M} (Step 104), and using equation I_{S}=(V_{R}/V_{M})·I_{M} to calculate a simulated compensation value I_{S} of the dynamic leakage current (Step 105), finally displaying the simulated compensation value I_{S} of the dynamic leakage current (Step 106), and finishing the test.

A test method according to present invention utilizes Ohm's law and the principle of constant ratio to calculate a dynamic leakage current simulated compensation through the following equation under a non-ideal input condition and to reach an ideal test value:

I_{S}=(V_{R}/V_{M})·I_{M}.

wherein V_{R}=designated standard test voltage value, V_{M}=actual test voltage value, I_{M}=actual dynamic leakage current value, and I_{S}=calculated (i.e., simulated) dynamic leakage current simulated compensation value.

That is, the test method having a dynamic leakage current simulated compensation function according to present invention utilizes the principle of using constant voltage to generate a constant current on a constant impedance. A computer program is used to set a voltage value required for a constant amount of leakage current measurement before performing a dynamic current test. During the test, if the system control device found the actual voltage value is different from the voltage value stored in the memory, it automatically calculates a dynamic leakage current simulated compensation value from the ratio of the voltage value stored in the memory and the actual voltage value and from a measured leakage current value.

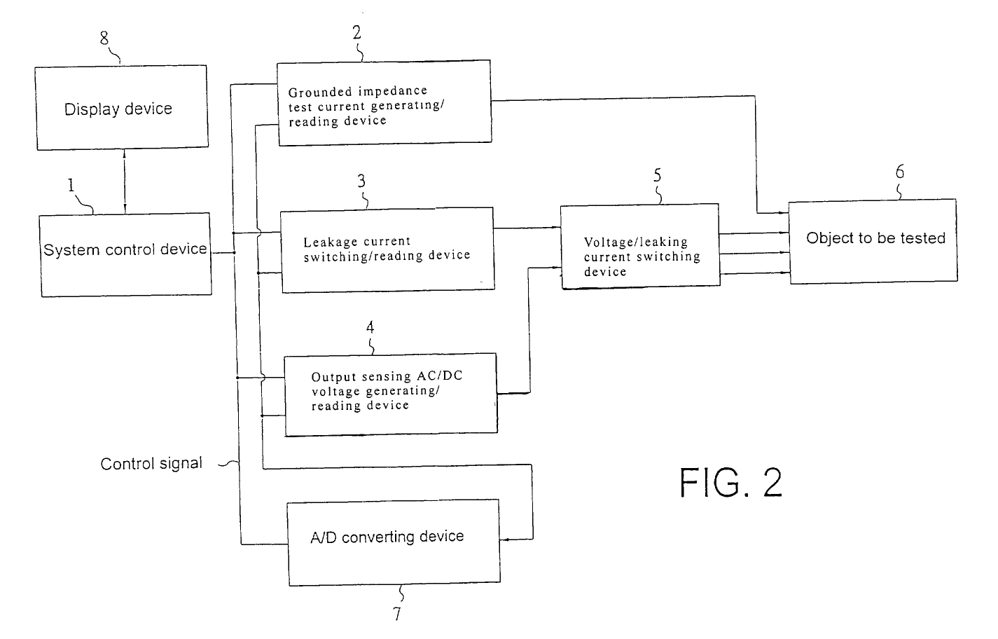

In FIG. 2, a five-in-one test device having a function of dynamic leakage current self-simulated compensation according to present invention comprises: a system control device 1 for selecting test condition via a grounded impedance test current generating/reading device 2 for testing ground impedance; a leakage current switching/reading device 3 for setting standard test voltage value V_{R} in a test device when performing the test, so that a simulated compensation value I_{S} of the dynamic leakage current can be calculated each time from voltage V_{M}, leakage current I_{M}, and said standard test voltage value V_{R} in accordance with the following equation: I_{S}=(V_{R}/V_{M})·I_{M}; an output sensing AC/DC voltage generating/reading device 4; and a digital/analog converting device 7 for conducting test on an objected 6 to be tested via a voltage/leakage-current converting device 5 in various conditions, returning the output to said control system 1 for analysis and calculation and sending the result to a display device 8.

As described above, a five-in-one safety specification test device according to present invention uses the feature of common grounded impedance to provide a test device having a function of dynamic leakage current self-simulated compensation and is capable of conducting tests such as a DC voltage test, an AC voltage test, an insulating impedance test, a grounded impedance test, and a dynamic leakage current test. This device will make self-compensation to the leakage current error generated by different input voltages during the dynamic leakage current test, so as to ensure the effect of precise test without additional apparatus such as a power supply.

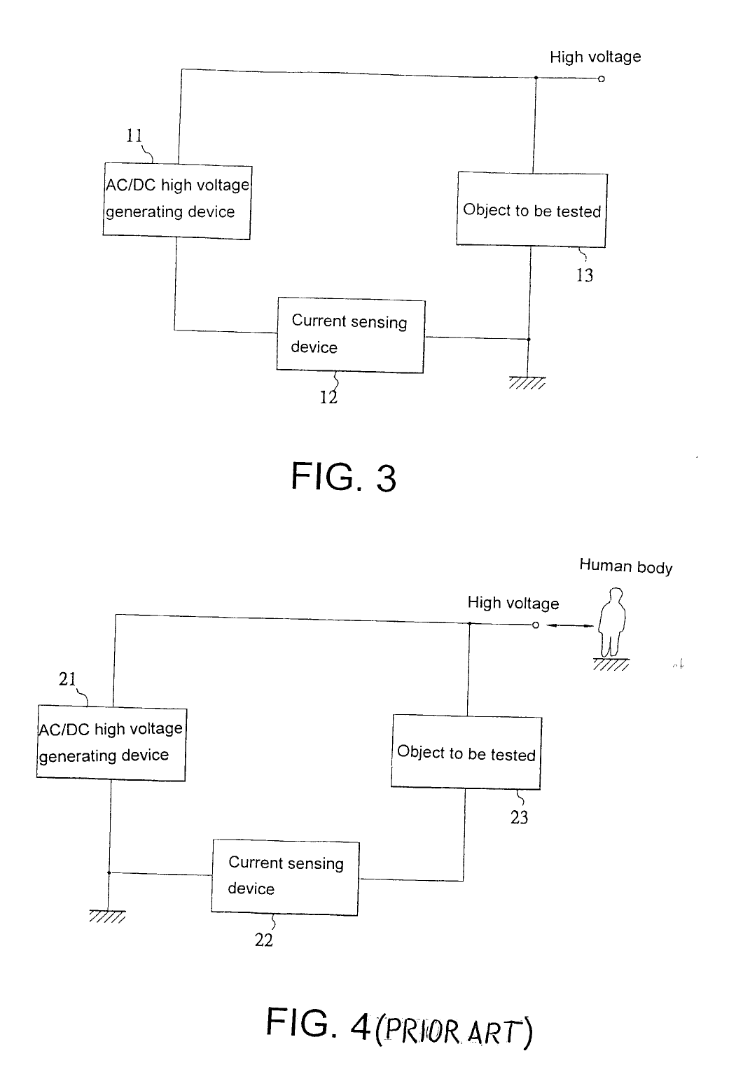

Moreover, according to the five-in-one safety specification test device of present invention, in addition to the five-in-one function, other test functions such as DC voltage test, AC voltage test, and insulating impedance is applicable by means of an output sensing high voltage generate/read device shown in FIG. 3. The difference between such device and a device of prior art shown in FIG. 4 is that the “output” current sensing device 12 is different from the “input” current sensing device 22 of the prior art. In this output current sensing device 12, a technique is adapted to judge instantly whether the high-voltage generating device (11,21) has already outputted a high voltage output that may cause fatal shock to object to be tested (13,23) or human body, and connect said current sensing device 12 and object to be tested (13) to a low voltage such as ground. Those who skilled in this technique will understand that present invention is not limited to above description and is allowed to have various modification and change, however, the spirit and scope of present invention is considered to fall within claims as following.

### List of Reference Numerals

1 system control device

2 ground impedance test current generating/reading device

3 Leakage current switching/reading device

4 Output sensing AC/DC voltage generating/reading current generating/reading device

5 Voltage leakage current switching device

6 object to be tested

7 analog/digital (A/D) converting device

8 display device

11,21 AC/DC high voltage generating device

12,22 current sensing device

13,23 object to be tested

What is claimed is:

1. A method for providing compensation current, which is a method used for testing leakage current in safety specification testing, the method comprising: using a standard test voltage value V_{R} as a standard voltage value for a subsequent compensation calculation; reading a test voltage value V_{M} and a leakage current I_{M} after connecting an object to be tested to a connecting point; and calculating a simulated compensation value of a dynamic leakage current I_{S} in accordance with a following equation: I_{S}=(V_{R}/V_{M})·I_{M}.

2. A test device, using the method according to claim 1, which is a multi-function test device for AC voltage test, DC voltage test, insulation impedance test, ground impedance test and line leakage current test, wherein the line leakage current test of the test device comprising: a fixed voltage power supply; a system control device, for providing selection of test and control signals for each of devices and connecting with a displaying device; a leakage current detection device, having an operating equation for calculating a compensation current for a leakage current and setting a voltage value for testing the leakage current, wherein a simulated compensation voltage of a dynamic leakage current is calculated by: connecting an object to be tested to a connecting point for reading a test voltage value and a leakage current value, and calculating the simulated compensation current of the dynamic leakage current by using the set voltage value, the test voltage value and leakage current value.

3. A multi-function test device, connecting with a displaying device and using a system control device to provide selection function for test and control signals for each of devices, having functions of AC voltage test, DC voltage test, insulation impedance test, ground impedance test and line leakage current test, wherein the line leakage current test of the multi-function test device comprising: a fixed voltage power supply; a system control device, for providing selection of test and control signals for each of devices and connecting with a displaying device; a leakage current detection device, having an operating equation for calculating a compensation current for a leakage current and setting a voltage value for testing the leakage current, wherein a simulated compensation value of a dynamic leakage current is calculated by: connecting an object to be tested to a connecting point for reading a test voltage value and a leakage current value, and calculating the simulated compensation value of the dynamic leakage current by using the set voltage value, the test voltage value and leakage current value.

4. The multi-function test device according to claim 3, wherein said AC voltage test and DC voltage test are capable of sensing output current, wherein said multi-function test device and the object to be tested are simultaneously connected to a low voltage.
